(19) United States
(12) Patent Application Publication
(10) Pub. No.: US 2025/0002330 A1
(43) Pub. Date: Jan. 2, 2025

(54) MICROELECTRONICS PACKAGE WITH VERTICALLY STACKED MEMS DEVICE AND CONTROLLER DEVICE

(71) Applicant: Qorvo US, Inc., Greensboro, NC (US)

(72) Inventors: Julio C. Costa, Oak Ridge, NC (US); Mickael Renault, San Jose, CA (US)

(21) Appl. No.: 18/884,654

(22) Filed: Sep. 13, 2024

Related U.S. Application Data
(63) Continuation of application No. 17/102,957, filed on Nov. 24, 2020, now Pat. No. 12,129,168.
(60) Provisional application No. 62/952,988, filed on Dec. 23, 2019.

(51) Int. Cl. B81B 7/00; B81C 3/00

(52) U.S. Cl. CPC B81B 7/007; B81C 3/001; B81B 2203/0315; B81B 2207/012; B81B 2207/096; B81B 2207/098; B81C 2203/037; B81C 2203/0792

(57) ABSTRACT

The present disclosure relates to a microelectronics package with a vertically stacked structure of a microelectromechanical systems (MEMS) device and a controller device. The MEMS device includes a MEMS component, a MEMS through-via, and a MEMS connecting layer configured to electrically connect the MEMS component with the MEMS through-via. The controller device includes a controlling component, a controller through-via, and a controller connecting layer configured to electrically connect the controlling component with the controller through-via. The controller through-via is in contact with the MEMS through-via, such that the controlling component in the controller device is configured to control the MEMS component in the MEMS device.

### RELATED APPLICATIONS

This application is a continuation of U.S. patent application Ser. No. 17/102,957, filed Nov. 24, 2020, which claims the benefit of provisional patent application Ser. No. 62/952,988, filed Dec. 23, 2019, the disclosures of which are hereby incorporated herein by reference in their entireties.

### FIELD OF THE DISCLOSURE

The present disclosure relates to a microelectronics package and a process for making the same, and more particularly to a microelectronics package with a vertically stacked structure of a microelectromechanical systems (MEMS) device and its controller device.

### BACKGROUND

The wide utilization of cellular and wireless devices drives the rapid development of radio frequency (RF) technologies. The substrates on which RF devices are fabricated play an important role in achieving high level performance in the RF technologies. Fabrications of the RF devices on conventional silicon substrates may benefit from low cost of silicon materials, a large scale capacity of wafer production, well-established semiconductor design tools, and well-established semiconductor manufacturing techniques.

Despite the benefits of using conventional silicon substrates for the RF device fabrications, it is well known in the industry that the conventional silicon substrates may have two undesirable properties for the RF devices: harmonic distortion and low resistivity values. The harmonic distortion is a critical impediment to achieving high level linearity in the RF devices built over silicon substrates. In addition, the low resistivity encountered in the silicon substrates may degrade quality factors (Q) at high frequencies of microelectromechanical systems (MEMS) or other passive components.

Stacked-device assembly technology currently attracts substantial attention in portable RF applications, due to the popularity of portable consumer electronic products, such as smart phones, tablet computers, and so forth. Stacked-device assemblies are designed to achieve electronics densification in a small footprint. However, the thickness of each stacked-device, especially the thickness of the silicon substrate for each stacked-device, may result in a large thickness of the final product, which may not meet low-profile requirements for modern portable applications.

Accordingly, to reduce deleterious harmonic distortion of the RF devices, and to accommodate the low-profile requirements for portable products, it is therefore an object of the present disclosure to provide an improved package design with enhanced performance and a reduced package size without expensive and complicated processes.

### SUMMARY

The present disclosure relates to a microelectronics package with a vertically stacked structure of a microelectromechanical systems (MEMS) device and its controller device. The disclosed microelectronics package includes a MEMS device and a controller device vertically stacked underneath the MEMS device. The MEMS device includes a MEMS device region at a top of the MEMS device, a stop layer underneath the MEMS device region, and a MEMS through-via that extends through the stop layer and into the MEMS device region. Herein, the MEMS device region includes a MEMS component and a MEMS connecting layer configured to electrically connect the MEMS component with the MEMS through-via. In addition, the controller device includes a controller bonding layer at a top of the controller device and configured to bond to the MEMS device, a controller device region underneath the controller bonding layer, and a controller through-via that extends through the controller bonding layer and into the controller device region. Herein, the controller device region includes a controlling component and a controller connecting layer configured to electrically connect the controlling component with the controller through-via. The controller through-via is in contact with the MEMS through-via, such that the controlling component in the controller device region is configured to control the MEMS component in the MEMS device region through the controller connecting layer, the controller through-via, the MEMS through-via, and the MEMS connecting layer.

In one embodiment of the microelectronics package, silicon crystal, which has no germanium, nitrogen, or oxygen content, does not exist between the MEMS device region and the controller device region.

In one embodiment of the microelectronics package, the MEMS through-via does not extend toward or into portions of the MEMS device region where the MEMS component is located, and the controller through-via does not extend toward or into portions of the controller device region where the controlling component is located.

In one embodiment of the microelectronics package, the stop layer in the MEMS device is formed of silicon oxide, and the controller bonding layer is formed of silicon oxide.

In one embodiment of the microelectronics package, the stop layer is at a bottom of the MEMS device and directly bonded with the controller bonding layer of the controller device.

In one embodiment of the microelectronics package, the MEMS device further includes a MEMS enhancement region underneath the stop layer and a MEMS bonding layer underneath the MEMS enhancement region. Herein, the MEMS through-via extends through the MEMS bonding layer, the MEMS enhancement region, the stop layer and into the MEMS device region. The MEMS enhancement region includes at least one of a MEMS barrier layer and a MEMS thermally conductive layer. The MEMS bonding layer underneath the MEMS enhancement region is at a bottom of the MEMS device and directly bonded with the controller bonding layer of the controller device. The MEMS bonding layer is formed of silicon oxide.

In one embodiment of the microelectronics package, between the stop layer and the MEMS enhancement region, there is a MEMS handle substrate with a thickness between 0 μm to 50 μm.

In one embodiment of the microelectronics package, the MEMS enhancement region includes the MEMS barrier layer underneath the stop layer and the MEMS thermally conductive layer underneath the MEMS barrier layer. The MEMS barrier layer is formed of silicon nitride with a thickness between 0.2 μm and 10 μm, and the MEMS thermally conductive layer is formed of aluminum nitride with a thickness between 0.1 μm and 20 μm.

In one embodiment of the microelectronics package, the MEMS device region further includes a MEMS cavity, MEMS dielectric layers, and a number of MEMS connecting layers that includes the MEMS connecting layer. The MEMS cavity is formed within the MEMS dielectric layers, and the MEMS component is located in the MEMS cavity, such that the MEMS component can be free to actuate. The MEMS connecting layers are partially covered by the MEMS dielectric layers and are configured to electrically connect the MEMES component to components outside the MEMS device region.

According to another embodiment, the microelectronics package further includes a number of bump structures, which are formed over the MEMS device region, and electrically coupled to the MEMS component through the plurality of MEMS connecting layers.

In one embodiment of the microelectronics package, the controller device region includes a back-end-of-line (BEOL) portion underneath the controller bonding layer, and a front-end-of-line (FEOL) portion underneath the BEOL portion. The FEOL portion includes a contact layer underneath the BEOL portion, an active layer underneath the contact layer, and isolation sections underneath the contact layer and surrounding the active layer. Herein, a combination of the active layer and the contact layer provides the controlling component. The BEOL portion includes controller dielectric layers, and a number of controller connecting layers that includes the controller connecting layer. The controller connecting layers are partially covered by the controller dielectric layers and are configured to electrically connect the controlling component in the FEOL portion to components outside the controller device region.

In one embodiment of the microelectronics package, the isolation sections extend vertically beyond a bottom surface of the active layer to define an opening within the isolation sections and underneath the active layer.

In one embodiment of the microelectronics package, the controller device further includes a controller enhancement region underneath the FEOL portion of the controller device region. The controller enhancement region includes at least one of a controller barrier layer and a controller thermally conductive layer. In addition, the controller enhancement region continuously covers bottom surfaces of the isolation sections and exposed surfaces within the opening so as to cover the active layer.

In one embodiment of the microelectronics package, the controller device further includes a passivation layer underneath the FEOL portion of the controller device region. The passivation layer continuously covers bottom surfaces of the isolation sections and exposed surfaces within the opening so as to cover the active layer. The passivation layer is formed of silicon dioxide.

According to another embodiment, the microelectronics package further includes a mold compound formed underneath the passivation layer. The mold compound has a thermal conductivity greater than 1 W/m·K and a dielectric constant less than 8.

In one embodiment of the microelectronics package, the controller device further includes a controller enhancement region underneath the passivation layer. The controller enhancement region includes at least one of a controller barrier layer and a controller thermally conductive layer.

According to another embodiment, the microelectronics package further includes a mold compound formed underneath the controller enhancement region. The mold compound has a thermal conductivity greater than 1 W/m·K and a dielectric constant less than 8.

In one embodiment of the microelectronics package, a bottom surface of each isolation section and the bottom surface of the active layer are coplanar, such that the FEOL portion of the controller device region has a flat bottom surface.

In one embodiment of the microelectronics package, the controller device further includes an oxide layer underneath the FEOL portion of the controller device region. Herein, the oxide layer continuously covers bottom surfaces of the isolation sections and the active layer. The oxide layer is formed of silicon dioxide.

In one embodiment of the microelectronics package, the FEOL portion further includes a body for the controlling component, which fills the opening and extends underneath the bottom surfaces of the isolation sections.

In one embodiment of the microelectronics package, the controller device further includes a controller enhancement region underneath the body. Herein, the controller enhancement region includes at least one of a controller barrier layer and a controller thermally conductive layer.

In one embodiment of the microelectronics package, the controlling component is a switch field-effect transistor (FET).

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary microelectronics package with vertically stacked devices according to one embodiment of the present disclosure.

FIG. 2 illustrates an alternative microelectronics package according to one embodiment of the present disclosure.

FIG. 3 illustrates an alternative microelectronics package according to one embodiment of the present disclosure.

FIGS. 4A-14 provide exemplary steps that illustrate a process to fabricate the exemplary microelectronics package illustrated in FIG. 1.

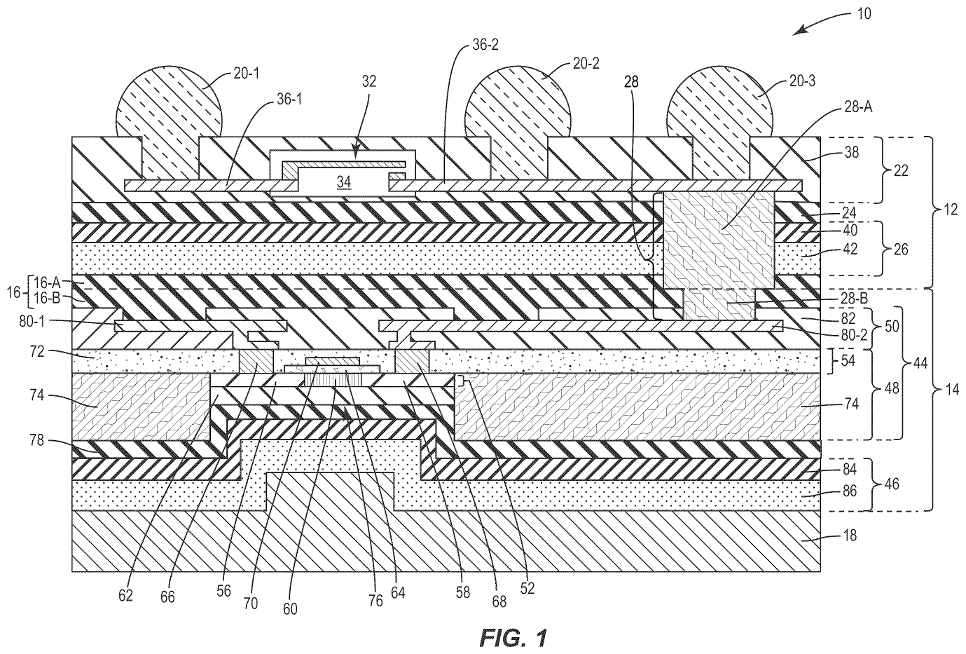

It will be understood that for clear illustrations, FIGS. 1-14 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

FIG. 1 illustrates an exemplary microelectronics package 10 with vertically stacked devices according to one embodiment of the present disclosure. For the purpose of this illustration, the microelectronics package 10 includes a microelectromechanical systems (MEMS) device 12, a controller device 14 vertically stacked with the MEMS device 12. Herein, the MEMS device 12 and the controller device 14 are bonded at a bonding region 16, which includes a MEMS bonding layer 16-A from the MEMS device 12 and a controller bonding layer 16-B from the controller device 14. In addition, the microelectronics package 10 may also include a mold compound 18 underneath the controller device 14, and multiple bump structures 20 over the MEMS device 12. In different applications, the microelectronics package 10 may include different stacked devices other than the MEMS device 12 and its controller device 14.

In the MEMS device 12, a MEMS device region 22 is at a top of the MEMS device 12, a stop layer 24 is underneath the MEMS device region 22, a MEMS enhancement region 26 is underneath the stop layer 24, the MEMS bonding layer 16-A is underneath the MEMS enhancement region 26, and a MEMS through-via 28-A that extends through the MEMS bonding layer 16-A, the MEMS enhancement region 26, and the stop layer 24, and extends into the MEMS device region 22.

In detail, the MEMS device region 22 includes a MEMS component 32, a MEMS cavity 34, MEMS connecting layers 36, and MEMS dielectric layers 38. Herein, the MEMS cavity 34 is formed within the MEMS dielectric layers 38, and the MEMS component 32, typically a switch, is located in the MEMS cavity 34, such that the MEMS component 32 can be free to actuate. The MEMS connecting layers 36 are partially covered by the MEMS dielectric layers 38, and are configured to electrically connect the MEMS component 32 in the MEMS cavity 34 to the bump structures 20. For the purpose of this illustration, a first bump structure 20-1 is connected to the MEMS component 32 through a first MEMS connecting layer 36-1, while a second bump structure 20-2 and a third bump structure 20-3 are connected to the MEMS component 32 through a second MEMS connecting layer 36-2. In different applications, there might be more MEMS connecting layers 36 and more/fewer bump structures 20 connected to the MEMS connecting layers in a different configuration.

The stop layer 24 is formed underneath the MEMS device region 22 and extends over an entire bottom surface of the MEMS device region 22. The stop layer 24 may be formed of silicon oxide with a thickness between 10 nm and 5000 nm. In some applications, there might be a thin MEMS handle substrate, with a thickness between 0 μm and 50 μm or between 0.1 μm and 20 μm, underneath the stop layer 24 (not shown).

The MEMS enhancement region 26 is formed underneath the stop layer 24, and extends over an entire bottom surface of the stop layer 24. If the thin MEMS handle substrate exists, the MEMS enhancement region 26 may be directly formed underneath the thin MEMS handle substrate. If the thin MEMS handle substrate does not exist (in a desired case), the MEMS enhancement region 26 may be directly formed underneath the stop layer 24.

The MEMS enhancement region 26 is configured to enhance reliability and/or thermal performance of the MEMS component 32. In one embodiment, the MEMS enhancement region 26 includes a MEMS barrier layer 40 formed underneath the stop layer 24, and a MEMS thermally conductive layer 42 formed underneath the MEMS barrier layer 40. Herein, the MEMS barrier layer 40 is formed of silicon nitride with a thickness between 2000 Å and 10 μm. The MEMS barrier layer 40 is configured to provide a superior barrier to moisture and impurities, which could diffuse into the MEMS cavity 34 and cause reliability concerns to the MEMS component 32. Moisture, for example, may diffuse readily through a silicon oxide layer (like the stop layer 24), but even a thin nitride layer (like the MEMS barrier layer 40) reduces the diffusion of the water molecule by several orders of magnitude, acting as an ideal barrier. In addition, the MEMS barrier layer 40 may also be engineered so as to provide additional tensile strain to the MEMS device region 22. Such strain may be beneficial in providing minimal warpage of the stacked layers. Furthermore, the MEMS barrier layer 40 may also provide thermal benefit to the MEMS device region 22.

The MEMS thermally conductive layer 42, which may be formed of aluminum nitride with a thickness between 0.1 μm and 20 μm, could provide superior thermal dissipation for the MEMS device region 22, in the order of 275 W/mk while retaining superior electrically insulating characteristics. The MEMS thermally conductive layer 42 might be very important to the overall thermal behavior of the stacked layers. If power dissipation is not a concern, then the MEMS thermally conductive layer 42 may be omitted. Due to different application needs, the entire MEMS enhancement region 26 might be omitted, or the MEMS barrier layer 40 might be omitted while the MEMS thermally conductive layer 42 might be retained.

The MEMS device 12 also includes the MEMS bonding layer 16-A for bonding to the controller device 14. The MEMS bonding layer 16A may be formed of silicon oxide. If the MEMS device 12 includes the MEMS enhancement region 26 with the MEMS barrier layer 40 and the MEMS thermally conductive layer 42, the MEMS bonding layer 16-A is formed directly underneath the MEMS thermally conductive layer 42. If the MEMS barrier layer 40 is retained while the MEMS thermally conductive layer 42 is omitted, the MEMS bonding layer 16-A is formed directly underneath the MEMS barrier layer 40. If the MEMS barrier layer 40 is omitted while the MEMS thermally conductive layer 42 is retained, the MEMS bonding layer 16-A is formed directly underneath MEMS thermally conductive layer 42. If the entire MEMS enhancement region 26 is omitted in the MEMS device 12, there might not be a need for the MEMS bonding layer 16-A, since the stop layer 24 may also be used for bonding to the controller device 14.

The MEMS through-via 28-A extends through the MEMS bonding layer 16-A, the MEMS enhancement region 26, and the stop layer 24, and extends into the MEMS device region 22. The MEMS through-via 28-A does not extend toward or into the portions of the MEMS device region 22 where the MEMS cavity 34 and the MEMS component 32 are located. The MEMS through-via 28-A (with the controller through-via 28-B, described in following paragraphs) is configured to electrically connect the MEMS device 12 and the controller device 14. For the purpose of this illustration, the MEMS through-via 28-A is connected to the MEMS component 32 through the second MEMS connecting layer 36-2. The MEMS through-via 28-A may be formed of copper.

The controller device 14 includes the controller bonding layer 16-B at a top of the controller device 14 for bonding to the MEMS bonding layer 16-A, so as to bond to the MEMS device 12. The MEMS bonding layer 16-A and the controller bonding layer 16-B are formed of a same material, such as silicon oxide, and are combined directly together as the bonding region 16. If the MEMS device 12 does not include the MEMS enhancement region 26 and the MEMS bonding layer 16-A, the controller bonding layer 16-B at the top of the controller device 14 might be directly bonded to the stop layer 24 of the MEMS device 12.

The controller device 14 also includes a controller device region 44 formed underneath the controller bonding layer 16-B, a controller through-via 28-B that extends through the controller bonding layer 16-B and into the controller device region 44, and a controller enhancement region 46 formed underneath the controller device region 44.

Notice that, between the MEMS device region 22 and the controller device region 44, there are the bonding regions 16 (the MEMS bonding layer 16-A and the controller bonding layer 16-B), optionally the MEMS enhancement region 26 (the MEMS barrier layer 40 and/or the MEMS thermally conductive layer 42), optionally the thin MEMS handle substrate (not shown), the stop layer 24, and the through-vias (the MEMS through-via 28-A and the controller through-via 28-B). In a desired case, there is no MEMS handle substrate, such that, silicon crystal, which has no germanium, nitrogen, or oxygen content, does not exist between the MEMS device region 22 and the controller device region 44. Each of the MEMS barrier layer 40, the MEMS thermally conductive layer 42, and the MEMS bonding layer 16-A is formed of silicon composite.

The controller device region 44 includes a front-end-of-line (FEOL) portion 48 and a back-end-of-line (BEOL) portion 50. The BEOL portion 50 is formed underneath the controller bonding layer 16-B, and the FEOL portion 48 is formed underneath the BEOL portion 50. In one embodiment, the FEOL portion 48 may be configured to provide a switch field-effect transistor (FET) that controls the MEMS component 32 in the MEMS device 12. The FEOL portion 48 includes an active layer 52 and a contact layer 54 over the active layer 52. The active layer 52 may include a source 56, a drain 58, and a channel 60 between the source 56 and the drain 58. In some applications, there might be a body 62 residing underneath the active layer 52. The body 62 may be formed of silicon with a thickness between 10 nm and 500 nm.

The contact layer 54 is formed over the active layer 52 and includes a gate structure 64, a source contact 66, a drain contact 68, and a gate contact 70. The gate structure 64 may be formed of silicon oxide, and extends horizontally over the channel 60 (i.e., from over the source 56 to over the drain 58). The source contact 66 is connected to and over the source 56, the drain contact 68 is connected to and over the drain 58, and the gate contact 70 is connected to and over the gate structure 64. An insulating material 72 may be formed around the source contact 66, the drain contact 68, the gate structure 64, and the gate contact 70 to electrically separate the source 56, the drain 58, and the gate structure 64. In different applications, the FEOL portion 48 may have different FET configurations or provide different device components to control the MEMS component 32.

In addition, the FEOL portion 48 also includes isolation sections 74, which reside underneath the insulating material 72 of the contact layer 54 and surround the active layer 52 (and surround the body 62 if the body 62 exists). The isolation sections 74 are configured to electrically separate the controller device 14, especially the active layer 52, from other devices formed in a common controller wafer (not shown). Herein, the isolation sections 74 may extend from a bottom surface of the contact layer 54 and vertically beyond a bottom surface of the active layer 52 (and beyond the body 62 if the body 62 exists) to define an opening 76 that is within the isolation sections 74 and underneath the active layer 52 (and underneath the body 62 if the body 62 exists). The isolation sections 74 may be formed of silicon dioxide, which may be resistant to etching chemistries such as tetramethylammonium hydroxide (TMAH), xenon difluoride (XeF₂), potassium hydroxide (KOH), sodium hydroxide (NaOH), or acetylcholine (ACH), and may be resistant to a dry etching system, such as a reactive ion etching (RIE) system with a chlorine-based gas chemistry or a fluorine-based gas chemistry.

In some applications, the active layer 52 may be passivated to achieve proper low levels of current leakage in the device. The passivation may be accomplished with deposition of a passivation layer 78 underneath the FEOL portion 48 of the controller device region 44. Herein, the passivation layer 78 may extend over an entire bottom surface of the FEOL portion 48, such that the passivation layer 78 continuously covers exposed surfaces within the opening 76 and bottom surfaces of the isolation sections 74. In some applications, the passivation layer 78 may only cover a bottom surface of the active layer 52 (covers a bottom surface of the body 62 if the body 62 exists) and resides within the opening 76 (not shown). The passivation layer 78 may be formed of silicon oxide.

The BEOL portion 50 is over the FEOL portion 48 and includes multiple controller connecting layers 80 formed within controller dielectric layers 82. The controller connecting layers 80 may have one or more top portions not covered by the controller dielectric layers 82, such that the controller through-via 28-B can be electrically connected to one of the uncovered top portions of the controller connecting layers 80. For the purpose of this illustration, a first controller connecting layer 80-1 is connected to the source contact 66 (may be used for other internal connections, not shown), and a second controller connecting layer 80-2 is configured to connect the drain contact 68 to the controller through-via 28-B.

The controller through-via 28-B, which extends through the controller bonding layer 16-B and into the controller device region 44, is in contact with and electrically connected with the MEMS through-via 28-A. The controller through-via 28-B does not extend toward or into the portions of the controller device region 44 where the switch FET (the active layer 52) provided in the FEOL portion 48 is located. The MEMS through-via 28-A and the controller through-via 28-B are combined directly together as the through-via structure 28. As such, the switch FET provided in the FEOL portion 48 of the controller device 14 could control the MEMS component 32 in the MEMS device 12 through the second controller connecting layer 80-2, the through-via structure 28, and the second MEMS connecting layer 36-2. In some applications, the MEMS through-via 28-A and the controller through-via 28-B may have different plane sizes and/or different vertical heights.

The controller enhancement region 46 is formed underneath the passivation layer 78. If there is no passivation layer 78, the controller enhancement region 46 is formed underneath the controller device region 44 and extends over the entire bottom surface of the FEOL portion 48, such that the controller enhancement region 46 continuously covers exposed surfaces within the opening 76 and bottom surfaces of the isolation sections 74 (not shown). If the passivation layer 78 is only formed underneath the active layer 52 and within the opening 76, the controller enhancement region 46 still continuously covers exposed surfaces (including the passivation layer 78) within the opening 76 and bottom surfaces of the isolation sections 74 (not shown). The controller enhancement region 46 is configured to enhance reliability and/or thermal performance of the controller device region 44, especially the active layer 52 in the controller device region 44.

In one embodiment, the controller enhancement region 46 includes a controller barrier layer 84 formed underneath the passivation layer 78, and a controller thermally conductive layer 86 formed underneath the controller barrier layer 84. Herein, the controller barrier layer 84 may be formed of silicon nitride with a thickness between 2000 Å and 10 μm. The controller barrier layer 84 is configured to provide a superior barrier to moisture and impurities, which could diffuse into the channel 60 of the active layer 52 and cause reliability concerns in the device. Moisture, for example, may diffuse readily through a silicon oxide layer (like the passivation layer 78), but even a thin nitride layer (like the controller barrier layer 84) reduces the diffusion of the water molecule by several orders of magnitude, acting as an ideal barrier. In addition, the controller barrier layer 84 may also be engineered so as to provide additional tensile strain to the controller device region 44. Such strain may be beneficial in providing additional improvement of electron mobility in n-channel devices. In some applications, the controller barrier layer 84 formed of silicon nitride may further passivate the active layer 52. In such a case, there may be no need for the passivation layer 78.

The controller thermally conductive layer 86, which may be formed of aluminum nitride with a thickness between 0.1 μm and 20 μm, could provide superior thermal dissipation for the controller device region 44, in the order of 275 W/mk while retain superior electrically insulating characteristics. The controller thermally conductive layer 86 might be very important to the overall thermal behavior of the stacked layers. If power dissipation is not a concern, then the controller thermally conductive layer 86 may be omitted. Due to different application needs, the entire controller enhancement region 46 might be omitted, or the controller barrier layer 84 might be omitted while the controller thermally conductive layer 86 might be retained.

The mold compound 18 is formed underneath the controller enhancement region 46. If there is no controller enhancement region 46, the mold compound 18 is formed underneath the passivation layer 78 and fills the opening 76 (not shown). The heat generated in the controller device region 44 may travel downward to a top portion of the mold compound 18 (through the controller enhancement region 46), especially to a portion underneath the active layer 52. It is therefore highly desirable for the mold compound 18 to have a high thermal conductivity, especially for a portion close to the active layer 52. The mold compound 18 may have a thermal conductivity between 1 W/m·K and 100 W/m·K, or between 7 W/m·K and 20 W/m·K. In addition, the mold compound 18 may have a low dielectric constant less than 8, or between 3 and 5 to yield low radio frequency (RF) coupling. The mold compound 18 may be formed of thermoplastics or thermoset polymer materials, such as polyphenylene sulfide (PPS), overmold epoxies doped with boron nitride, alumina, carbon nanotubes, or diamond-like thermal additives, or the like, and may have a thickness between 200 μm and 500 μm.

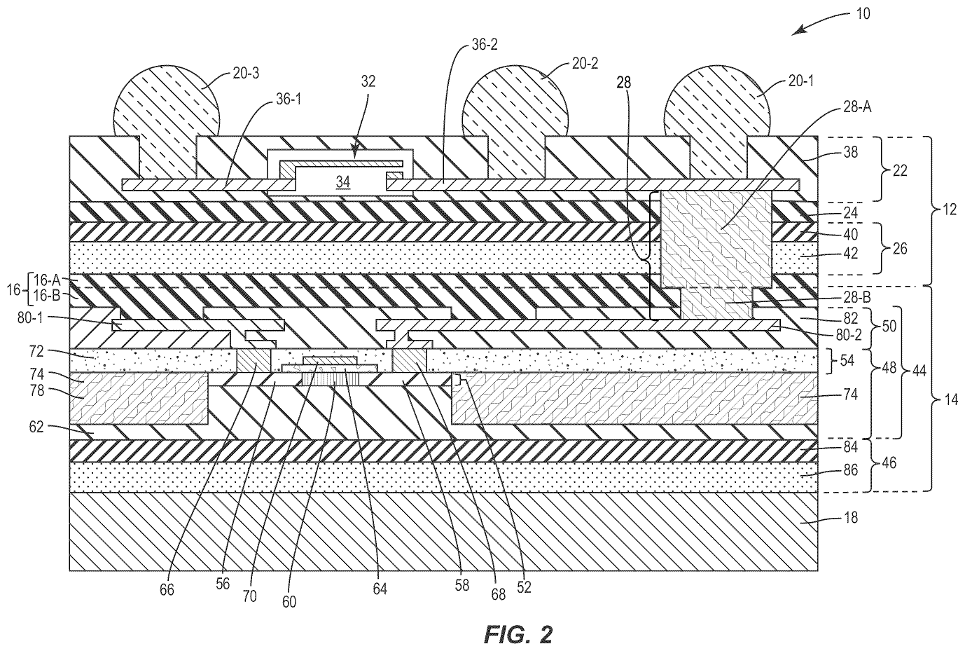

In some applications, the controller device region 44 may be formed from a conventional complementary metal-oxide semiconductor (CMOS) wafer, and the body 62 may extend vertically beyond the isolation sections 74, as illustrated in FIG. 2. As such, there is no opening 76 that resides within the isolation sections 74. In addition, a portion of the body 62 may extend underneath the bottom surfaces of the isolation sections 74. In this embodiment, the body 62 is thick enough, and there might not be a need to further passivate the active layer 52. The passivation layer 78 might be omitted, and the controller enhancement region 46 is formed directly underneath the body 62.

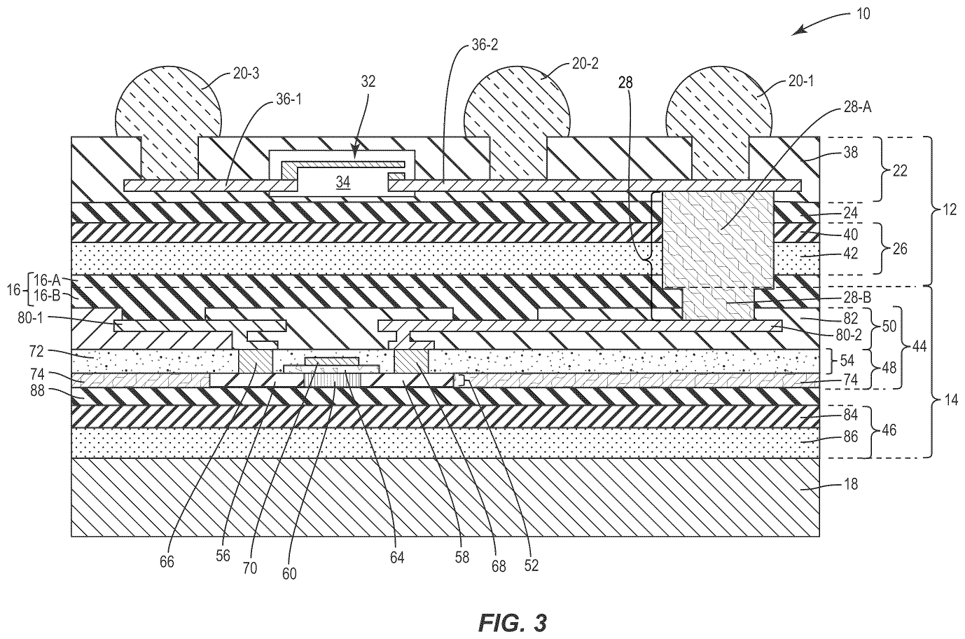

In some applications, the controller device region 44 may be formed from a silicon-on-insulator (SOI) CMOS wafer, which includes a silicon epitaxy layer, a silicon substrate, and a buried oxide (BOX) layer sandwiched between the silicon epitaxy layer and the silicon substrate (not shown). The controller device region 44 is formed by fabricating device elements in or on the silicon epitaxy layer of the SOI CMOS wafer, and resides over an oxide layer 88 that is the BOX layer of the SOI CMOS wafer, as illustrated in FIG. 3. In this embodiment, the active layer 52 and the isolation sections 74 formed over the oxide layer 88, and the bottom surface of each isolation section 74 does not extend vertically beyond the bottom surface of the active layer 52, such that the opening 76 is omitted. In addition, the active layer 52 does not need an extra passivation layer, since the oxide layer 88 (which is formed of silicon oxide and formed underneath the active layer 52) passivates the active layer 52. The oxide layer 88 continuously covers the bottom surface of the active layer 52 and bottom surfaces of the isolation sections 74, the controller enhancement region 46 formed underneath the oxide layer 88.

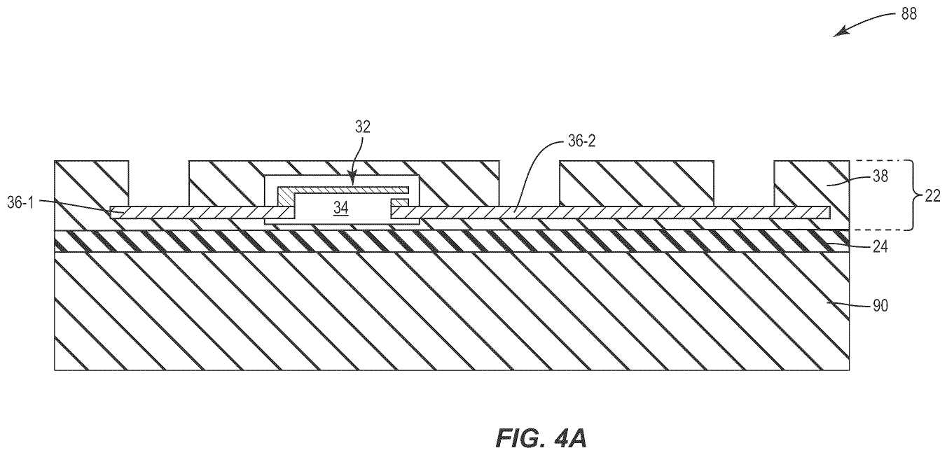

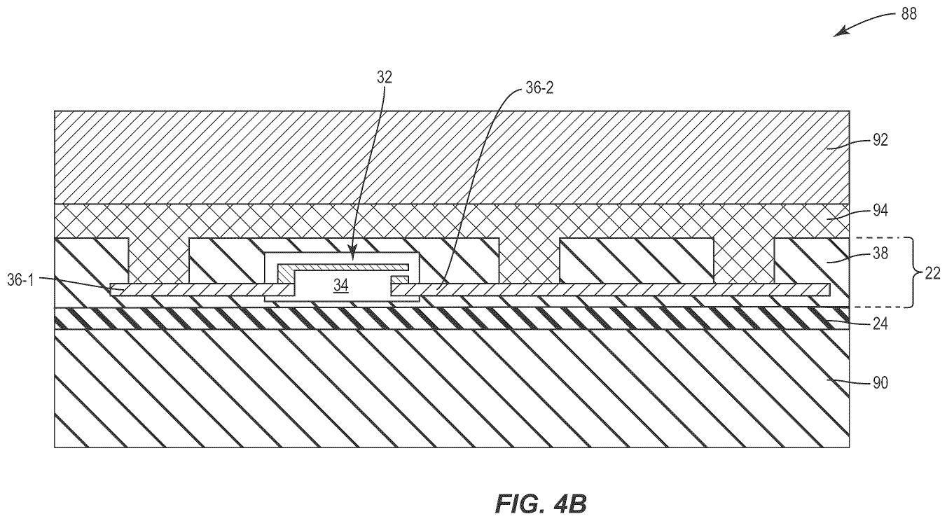

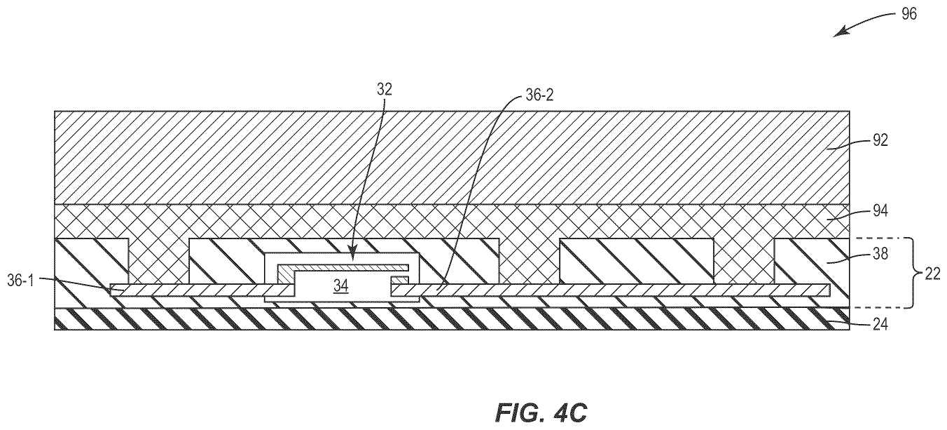

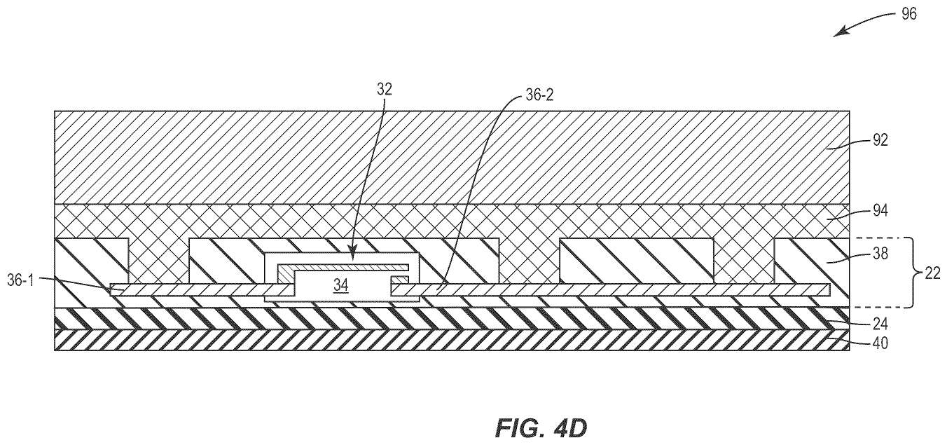

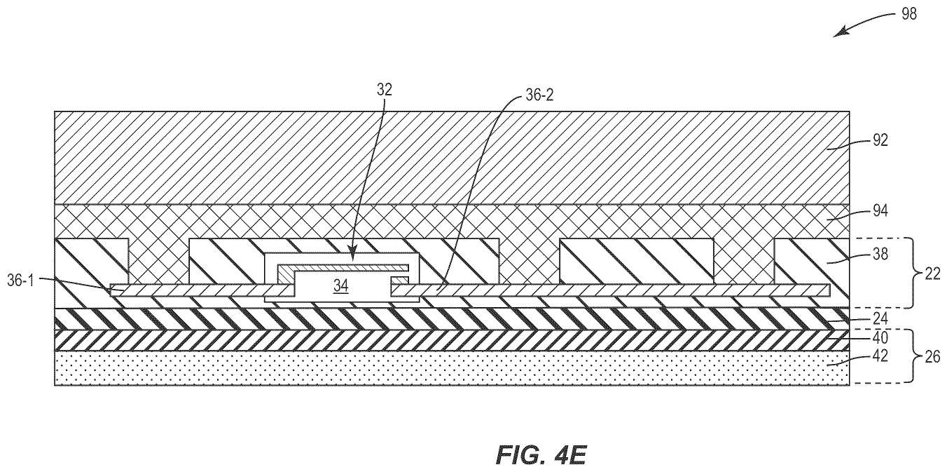

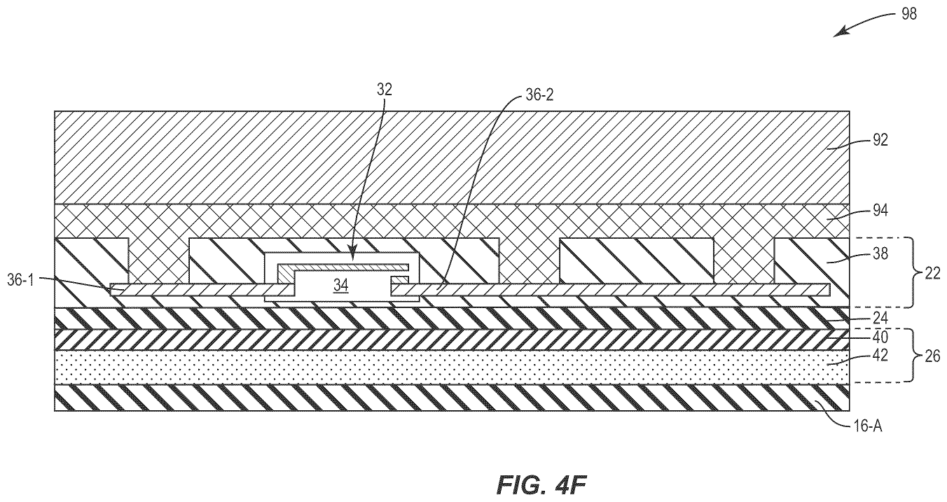

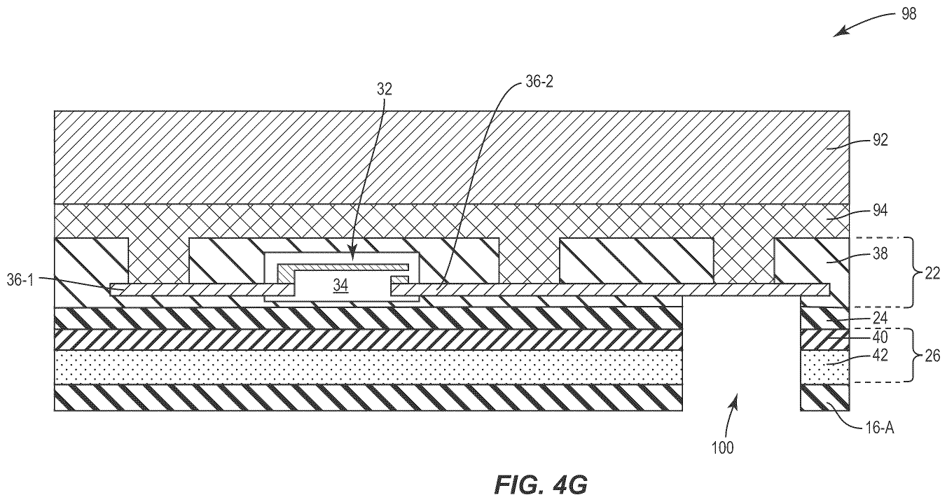

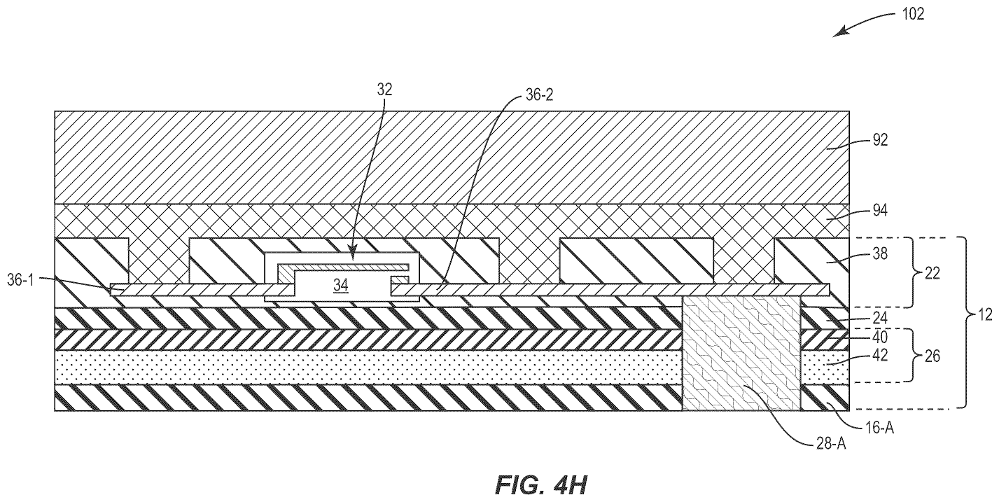

FIGS. 4A-14 provide an exemplary wafer-level fabricating and packaging process that illustrates steps to manufacture the exemplary microelectronics package 10 shown in FIG. 1. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 4A-14.

With reference to FIGS. 4A through 4I, a MEMS wafer which includes the MEMS device 12 is prepared for the microelectronics package 10. Initially, a starting MEMS wafer 89 is provided as illustrated in FIG. 4A. The starting MEMS wafer 89 includes the MEMS device region 22 at a top of the starting MEMS wafer 89, the stop layer 24 underneath the MEMS device region 22, and a MEMS handle substrate 90 underneath the stop layer 24. Herein, the MEMS device region 22 includes the MEMS component 32, the MEMS cavity 34, the MEMS connecting layers 36, and the MEMS dielectric layers 38. The MEMS cavity 34 is formed within the MEMS dielectric layers 38, and the MEMS component 32, typically a switch, is located in the MEMS cavity 34, such that the MEMS component 32 can be free to actuate. The MEMS connecting layers 36, which are configured to electrically connect the MEMS component 32 in the MEMS cavity 34 to external components outside the MEMS device region 22, are partially covered by the MEMS dielectric layers 38. For the purpose of this illustration, a top surface portion of the first MEMS connecting layer 36-1 and top surface portions of the second MEMS connecting layer 36-2 are exposed through the MEMS dielectric layers 38. In different applications, there might be more MEMS connecting layers 36 and more/fewer surface portions of the MEMS connecting layers 36 are exposed through the MEMS dielectric layers 38. The stop layer 24 extends over the entire bottom surface of the MEMS device region 22, so as to separate the MEMS device region 22 from the MEMS handle substrate 90. The MEMS handle substrate 90 may be formed of a conventional silicon with low cost.

Next, the starting MEMS wafer 89 is then mounted to a temporary carrier 92, as illustrated in FIG. 4B. The starting MEMS wafer 89 may be mounted to the temporary carrier 92 via a mounting layer 94, which provides a planarized surface to the temporary carrier 92. The temporary carrier 92 may be a thick silicon wafer from a cost and thermal expansion point of view, but may also be constructed of glass, sapphire, or any other suitable carrier material. The mounting layer 94 may be a span-on polymeric adhesive film, such as the Brewer Science WaferBOND line of temporary adhesive materials.

The MEMS handle substrate 90 is then selectively removed to provide an etched MEMS wafer 96, as illustrated in FIG. 4C. The selective removal may stop at the stop layer 24. Removing the MEMS handle substrate 90 may be provided by a mechanical grinding process and an etching process, or provided by the etching system itself. As an example, the MEMS handle substrate 90 may be ground to a thinner thickness to reduce the following etching time. An etching process is then performed to substantially remove the remaining MEMS handle substrate 90. Herein, substantially removing the remaining MEMS handle substrate 90 refers to removing the MEMS handle substrate until at most 50 μm or 20 μm of the MEMS handle substrate remains. In a desired case, the MEMS handle substrate may be completely removed. Since the MEMS handle substrate 90 and the stop layer 24 have different reactions to a same etching technique (for instance: different etching speeds with a same etchant), the etching system may be capable of identifying the presence of the stop layer 24, and capable of indicating when to stop the etching process. The etching process may be provided by a wet etching system with an etchant chemistry, which is at least one of TMAH, KOH, NaOH, ACH, and XeF₂, or a dry etching system, such as a reactive ion etching system with a chlorine-based gas chemistry or a fluorine-based gas chemistry. During the removal process, the mounting layer 94 and the temporary carrier 92 protect the MEMS device region 22.

After the substantial removal of the MEMS handle substrate 90, the MEMS barrier layer 40 is applied underneath the stop layer 24, as illustrated in FIG. 4D. If a thin portion of the MEMS handle substrate 90 has remained, the MEMS barrier layer 40 may be directly applied underneath the remaining MEMS handle substrate 90 (not shown). If there is no MEMS handle substrate remaining, the MEMS barrier layer 40 may be directly formed underneath the stop layer 24. In one embodiment, the MEMS barrier layer 40 covers an entire bottom surface of the stop layer 24. The MEMS barrier layer 40 is formed of silicon nitride with a thickness between 2000 Å and 10 μm. The MEMS barrier layer 40 is configured to provide a superior barrier to moisture and impurities, which could diffuse into the MEMS cavity 34 and cause reliability concerns to the MEMS component 32. Moisture, for example, may diffuse readily through a silicon oxide layer (like the stop layer 24), but even a thin nitride layer (like the MEMS barrier layer 40) reduces the diffusion of the water molecule by several orders of magnitude, acting as an ideal barrier. In addition, the MEMS barrier layer 40 may also be engineered so as to provide additional tensile strain to the MEMS device region 22. Such strain may be beneficial in providing minimal warpage of the stacked layers. Furthermore, the MEMS barrier layer 40 may also provide thermal benefit to the MEMS device region 22. The MEMS barrier layer 40 may be formed by a chemical vapor deposition system such as a plasma enhanced chemical vapor deposition (PECVD) system, or an atomic layer deposition system, such as plasma enhanced atomic layer deposition (PEALD) system.

The MEMS thermally conductive layer 42 is then applied underneath the MEMS barrier layer 40 to form the MEMS enhancement region 26, as illustrated in FIG. 4E. The MEMS thermally conductive layer 42, which may be formed of aluminum nitride with a thickness between 0.1 μm and 20 μm, could provide superior thermal dissipation for the MEMS device region 22, in the order of 275 W/mk while retaining superior electrically insulating characteristics. If power dissipation is not a concern of a final product, then the MEMS thermally conductive layer 42 may be omitted (not shown). In some applications, the entire MEMS enhancement region 26 might be omitted (not shown), or the MEMS barrier layer 40 might be omitted while the MEMS thermally conductive layer 42 might be applied directly underneath the stop layer 24 (not shown). The MEMS thermally conductive layer 42 may be formed by Chemical vapor deposition (CVD), atomic layer deposition system (ALD), or other similar methods known to those skilled in the art of semiconductor processing.

If the MEMS enhancement region 26 (including the MEMS barrier layer 40 and/or the MEMS thermally conductive layer 42) is applied underneath the stop layer 24, it is necessary to add the MEMS bonding layer 16-A underneath the MEMS enhancement region 26, as illustrated in FIG. 4F. The MEMS bonding layer 16-A is configured to be used at a later part of the process to connect to a controller wafer. The MEMS bonding layer 16A may be formed of silicon oxide, and is engineered to have a proper thickness for subsequent planarization and bonding steps. If the entire MEMS enhancement region 26 is omitted, there might not be a need for the MEMS bonding layer 16-A, since the stop layer 24 may also be used for bonding to the controller wafer.

Next, a MEMS via cavity 100 is formed through the MEMS bonding layer 16-A, the MEMS enhancement region 26, and the stop layer 24, and extends into the MEMS device region 22 to expose a bottom surface portion of the second MEMS connecting layer 36-2, as illustrated in FIG. 4G. The MEMS via cavity 100 does not extend through or into the portions of the MEMS device region 22 where the MEMS cavity 34 and the MEMS component 32 are located. The MEMS via cavity 100 may have a shape of a cuboid, a polygon, a cylinder, or a cone and has a depth greater than a thickness combination of the MEMS bonding layer 16-A, the MEMS enhancement region 26, and the stop layer 24. The MEMS via cavity 100 may be formed by a photo masking process and an etching process. The etching process is designed to be selective to metals, which means the etching process proceeds (removing portions of the MEMS bonding layer 16-A, the MEMS enhancement region 26, and the stop layer 24) until the second MEMS connecting layer 36-2 is reached.

The MEMS through-via 28-A is then formed in the MEMS via cavity 100 to complete a MEMS wafer 102 including the MEMS device 12, as illustrated in FIG. 4H. The MEMS through-via 28-A may be formed by filling the MEMS via cavity 100 with one or more appropriate materials. The appropriate material is required to be electrically conductive, such as platinum, gold, silver, copper, aluminum, tungsten, titanium, electrically conductive epoxy, or other suitable materials.

For defect-free and void-free wafer slice bonding, a backside of the MEMS wafer 102 need to be planarized with a nano-meter range flatness. Chemical mechanical polishing (CMP) technology may be utilized in the planarization process. Since the backside of the MEMS wafer 102 contains regions of both silicon oxide (the MEMS bonding layer 16-A) and electrically conductive material (the MEMS through-via 28-A), a combination of different CMP slurries and wheels may be necessary. If the MEMS through-via 28-A is formed of copper and will be bonded to another copper via using hybrid copper-copper bonding, it is desirable that the MEMS through-via 28-A be recessed by an appropriate amount compared to the MEMS bonding layer 16-A, as illustrated in FIG. 4I. Such recess 104 (from a planarized bottom surface of the MEMS bonding layer 16-A to a planarized bottom surface of the MEMS through-via 28-A) has a depth between 0.2 nm and 200 nm. This can be accomplished with a proper choice of copper/oxide slurries.

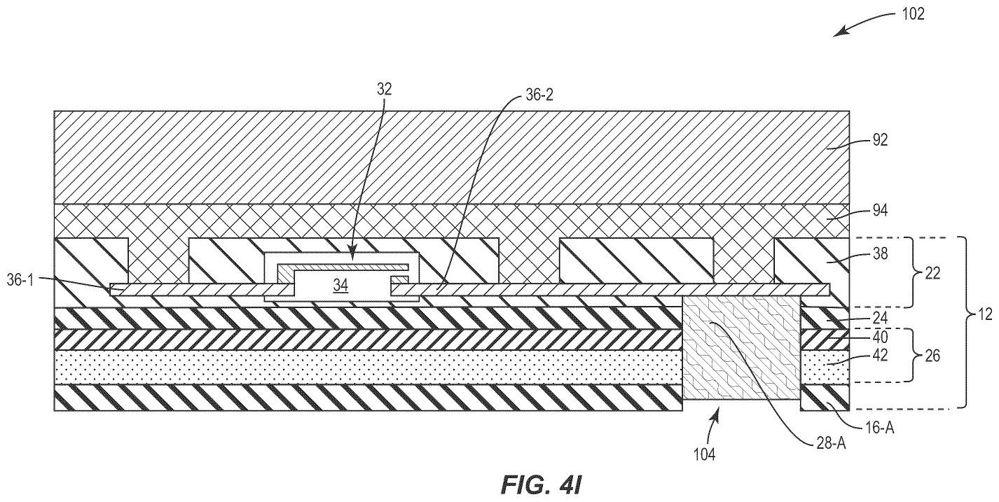

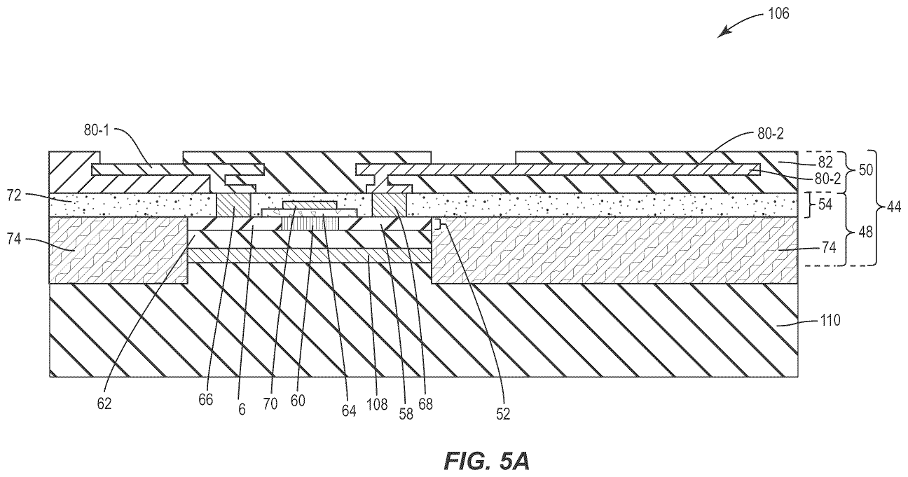

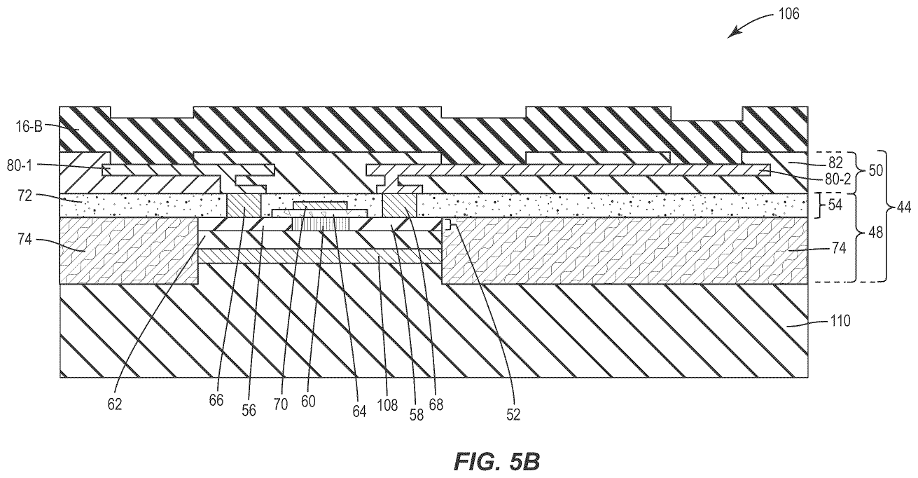

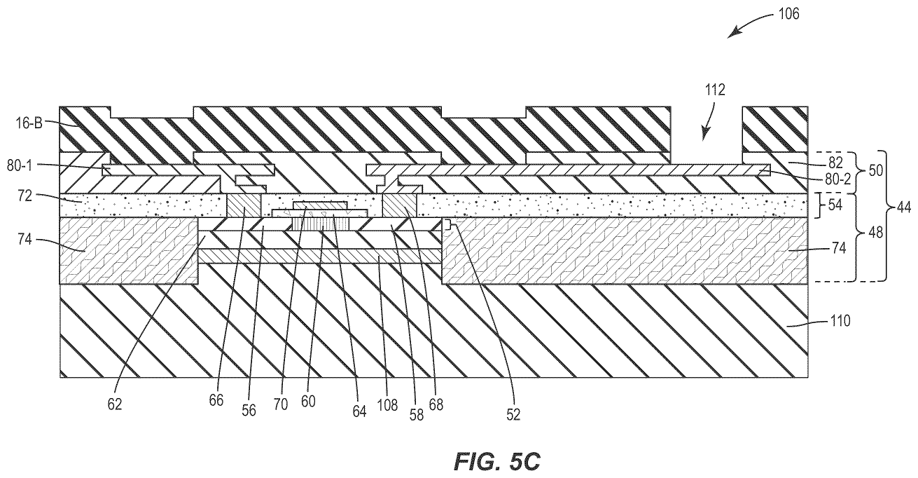

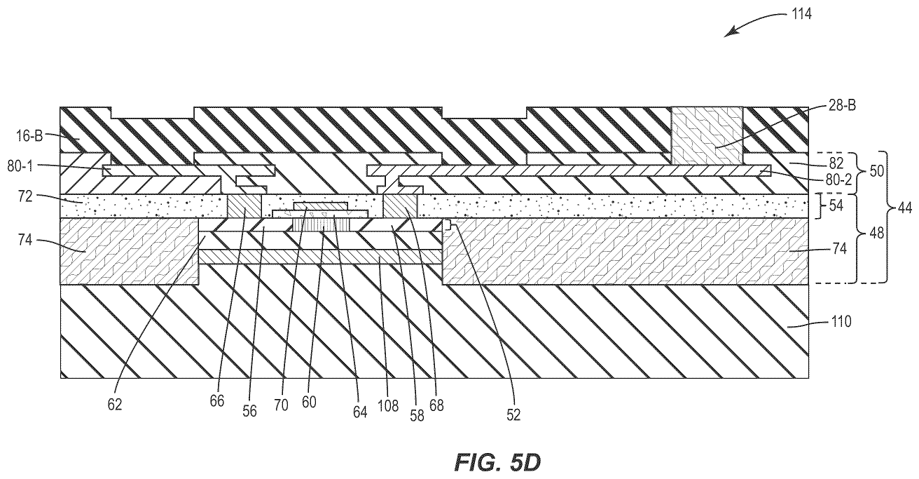

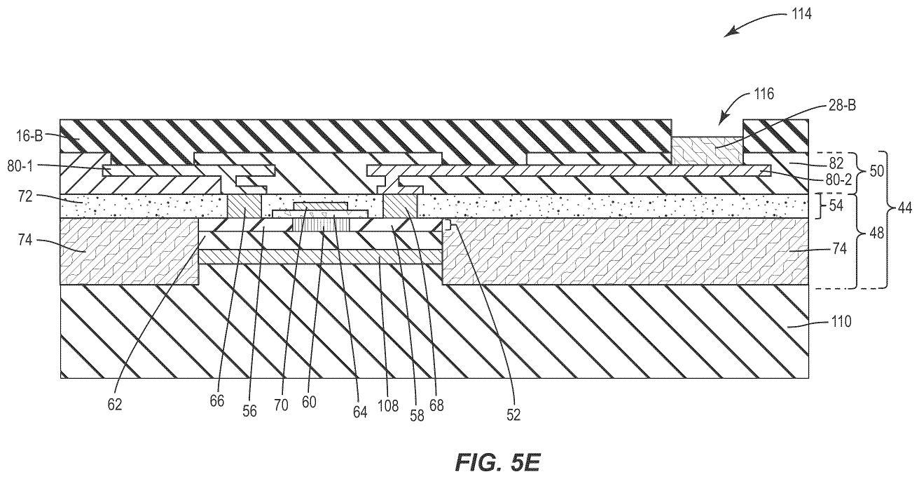

With reference to FIGS. 5A through 5E, a controller wafer which includes the controller device region 44 is prepared for the microelectronics package 10. Initially, a starting controller wafer 106 is provided as illustrated in FIG. 5A. The starting controller wafer 106 includes the controller device region 44 with the FEOL portion 48 and the BEOL portion 50, an interfacial layer 108, and a controller handle substrate 110.

The BEOL portion 50 is formed over the FEOL portion 48 and includes the controller connecting layers 80 formed within the controller dielectric layers 82. The controller connecting layers 80 may have one or more top portions not covered by the controller dielectric layers 82, such that the controller connecting layers 80 may be electrically connected to external components not within the starting controller wafer 106.

The FEOL portion 48, which may be configured to provide a switch FET for component controlling, includes the active layer 52 and the contact layer 54. The active layer 52 may include the source 56, the drain 58, and the channel 60 between the source 56 and the drain 58. In some applications, there might be the body 62 residing underneath the active layer 52. The body 62 may be formed of silicon with a thickness between 10 nm and 500 nm.

The contact layer 54, which is formed underneath the BEOL portion 50 and over the active layer 52, is configured to connect the active layer 52 to the BEOL portion 52. The contact layer 54 includes the gate structure 64, the source contact 66, the drain contact 68, and the gate contact 70. The gate structure 64 may be formed of silicon oxide, and extends horizontally over the channel 60 (i.e., from over the source 56 to over the drain 58). The source contact 66 is connected to and over the source 56, the drain contact 68 is connected to and over the drain 58, and the gate contact 70 is connected to and over the gate structure 64. The insulating material 72 may be formed around the source contact 66, the drain contact 68, the gate structure 64, and the gate contact 70 to electrically separate the source 56, the drain 58, and the gate structure 64. For the purpose of this illustration, the first controller connecting layer 80-1 in the BEOL 50 is connected to the source contact 66 and the second controller connecting layer 80-2 of the BEOL 50 is connected to the drain contact 68. In different applications, the FEOL portion 48 may have different FET configurations or provide different device components for controlling.

In addition, the FEOL portion 48 also includes the isolation sections 74, which reside underneath the insulating material 72 of the contact layer 54 and surround the active layer 52 (also surround the body 62 if the body 62 exists). The isolation sections 74 are configured to electrically separate the active layer 52 from other devices formed in the common controller wafer 106 (not shown). Herein, the isolation sections 74 may extend from the bottom surface of the contact layer 54 and vertically beyond the bottom surface of the active layer 52 (and beyond the body 62 if the body 62 exists). The isolation sections 74 may be formed of silicon dioxide, which may be resistant to etching chemistries such as tetramethylammonium hydroxide (TMAH), xenon difluoride (XeF₂), potassium hydroxide (KOH), sodium hydroxide (NaOH), or acetylcholine (ACH), and may be resistant to a dry etching system, such as a reactive ion etching (RIE) system with a chlorine-based gas chemistry.

The interfacial layer 108 resides underneath the active layer 52 (underneath the body 62 if the body 62 exists) and is surrounded by the isolation sections 74. In one embodiment, the bottom surfaces of the isolation section 74 may extend vertically beyond a bottom surface of the interfacial layer 108. The controller handle substrate 110 resides underneath the interfacial layer 108, and portions of the controller handle substrate 110 may extend underneath the isolation sections 74. As such, the interfacial layer 108 and the isolation sections 74 separate the active layer 52 and the controller handle substrate 110. The interfacial layer 108 may be formed of silicon germanium (SiGe), and the controller handle substrate 110 may be formed of a conventional silicon with low cost.

Next, the controller bonding layer 16-B is formed over the BEOL portion 50 of the controller device region 44, as illustrated in FIG. 5B. The controller bonding layer 16-B is formed of a same material as the MEMS bonding layer 16-A, such as silicon oxide. The controller bonding layer 16-B is engineered to have a proper thickness for subsequent planarization and bonding steps.

A controller via cavity 112 is then formed through the controller bonding layer 16-B, and extends into the BEOL portion 50 of the controller device region 44 to expose a top surface portion of the second controller connecting layer 80-2, as illustrated in FIG. 5C. The controller via cavity 112 does not extend toward or into the portions of the controller device region 44 where the switch FET (the active layer 52) provided in the FEOL portion 48 is located. The controller via cavity 112 may have a shape of a cuboid, a polygon, a cylinder, or a cone and has a depth greater than a thickness of the controller bonding layer 16-B. The controller via cavity 112 may be formed by a photo masking process and an etching process. The etching process is designed to be selective to metals, which means the etching process removes portions of the controller bonding layer 16-B (and maybe portions of controller dielectric layers 82) until the second controller connecting layer 80-2 is reached.

The controller through-via 28-B is formed in the controller via cavity 112 to complete a controller wafer 114 including the controller device region 44, as illustrated in FIG. 5D. The controller through-via 28-B may be formed by filling the controller via cavity 112 with one or more appropriate materials. The appropriate material is required to be electrically conductive, such as platinum, gold, silver, copper, aluminum, tungsten, titanium, electrically conductive epoxy, or other suitable materials.

For defect-free and void-free wafer slice bonding, a topside of the controller wafer 114 needs to be planarized with a nano-meter range flatness, as illustrated in FIG. 5E. The CMP technology may be utilized in the planarization process. Since the topside of the controller wafer 114 contains regions of both silicon oxide (the controller bonding layer 16-B) and electrically conductive material (the controller through-via 28-B), a combination of different CMP slurries and wheels may be necessary. If the controller through-via 28-B is formed of copper and will be bonded to the MEMS through-via 28-A using hybrid copper-copper bonding, it is desirable that the controller through-via 28-B be recessed by an appropriate amount compared to the controller bonding layer 16-B. Such recess 116 (from a planarized top surface of the controller bonding layer 16-B to a planarized top surface of the controller through-via 28-B) has a depth between 0.2 nm and 200 nm. This can be accomplished with a proper choice of copper/oxide slurries.

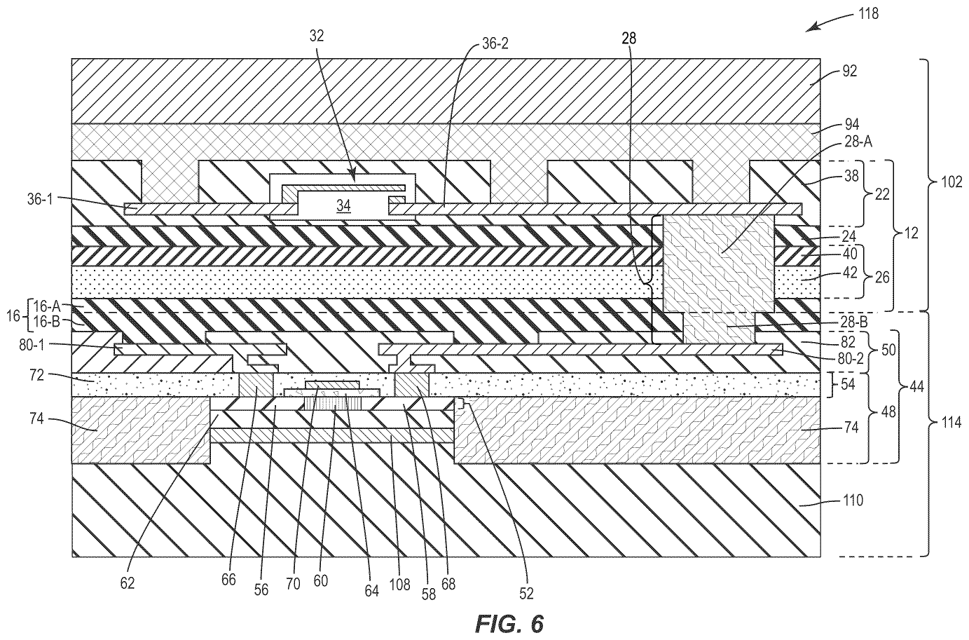

After the MEMS wafer 102 and the controller wafer 114 are formed, a bonding step is applied to form a precursor package 118, as illustrated in FIG. 6. The MEMS wafer 102 is placed over the controller wafer 114, such that the bottom surface of the MEMS bonding layer 16-A directly faces the top surface of the controller bonding layer 16-B. Suitable wafer alignment tools may be used to align the MEMS wafer 102 with the controller wafer 114, such that the MEMS through-via 28-A in the MEMS wafer 102 is vertically aligned with the controller through-via 28-B in the controller wafer 114.

A number of different methods may be utilized to implement the bonding step, and one of them is called direct bonding (DB) process. In the DB process, first bonding is achieved between the MEMS bonding layer 16-A and the controller bonding layer 16-B at a room temperature. Since the bottom surface of the MEMS bonding layer 16-A of the MEMS wafer 102 and the top surface of the controller bonding layer 16-B of the controller wafer 114 are properly planarized (flat enough in nano meter range), when the MEMS wafer 102 and the controller wafer 114 are brought together, an intimate connection will exist between the MEMS bonding layer 16-A and the controller bonding layer 16-B. Then second bonding between the MEMS through-via 28-A in the MEMS wafer 102 and the controller through-via 28-B in the controller wafer 114 could be achieved by careful heating cycles. If the MEMS through-via 28-A and the controller through-via 28-B are formed of copper, the heating cycles compress the copper-copper metal joints and create a high quality copper-copper low resistance bond. The MEMS through-via 28-A and the controller through-via 28-B are bonded directly together to form the through-via structure 28. As such, the switch FET provided in the controller device region 44 could control the MEMS component 32 in the MEMS device region 22 through the second controller connecting layer 80-2, the through-via structure 28, and the second MEMS connecting layer 36-2.

Notice that, between the MEMS device region 22 in the MEMS wafer 102 and the controller device region 44 in the controller wafer 114, there are the bonding region 16 (the MEMS bonding layer 16-A and the controller bonding layer 16-B), optionally the MEMS enhancement region 26 (the MEMS barrier layer 40 and/or the MEMS thermally conductive layer 42), optionally the thin MEMS handle substrate 90 (not shown), the stop layer 24, and the through-via structure 28 (the MEMS through-via 28-A and the controller through-via 28-B). In a desire case, there is no portion of the MEMS handle substrate 90 remained, such that, silicon crystal, which has no germanium, nitrogen, or oxygen content, does not exist between the MEMS device region 22 and the controller device region 44. Each of the MEMS barrier layer 40, the MEMS thermally conductive layer 42, and the MEMS bonding layer 16-A is formed of silicon composite.

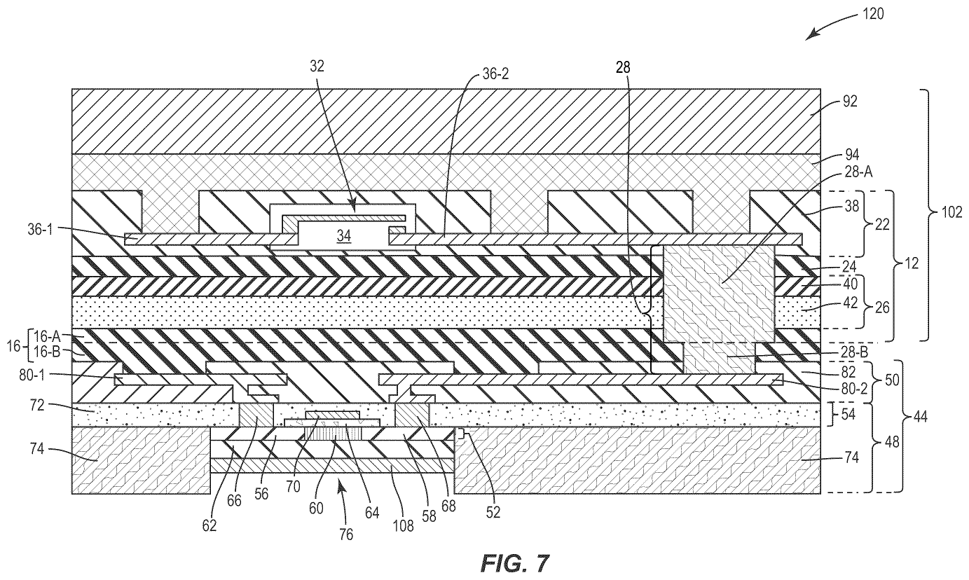

The controller handle substrate 110 is then selectively removed to provide an etched package 120, as illustrated in FIG. 7. Since the controller handle substrate 110 and the interfacial layer 108 have different germanium concentrations, they may have different reactions to a same etching technique (for instance: different etching speeds with a same etchant). Consequently, the etching system may be capable of identifying the presence of the interfacial layer 108 (presence of germanium), and capable of indicating when to stop the etching process. As such, the selective removal stops at or into the interfacial layer 108. Removing the controller handle substrate 110 may be provided by a mechanical grinding process and an etching process or provided by the etching system itself. As an example, the controller handle substrate 110 may be ground to a thinner thickness to reduce the following etching time. An etching process is then performed to remove the remaining controller handle substrate 110. The etching process may be provided by a wet etching system with an etchant chemistry, which is at least one of TMAH, KOH, NaOH, ACH, and XeF₂, or a dry etching system, such as a reactive ion etching system with a chlorine-based gas chemistry or a fluorine-based gas chemistry. If the isolation sections 74 extend vertically beyond the interfacial layer 108, the removal of the controller handle substrate 110 will provide the opening 76 underneath the interfacial layer 108 (of course underneath the active layer 52) and within the isolation sections 74. During the removal process, the isolation sections 74 are not removed and protect sides of the active layer 52.

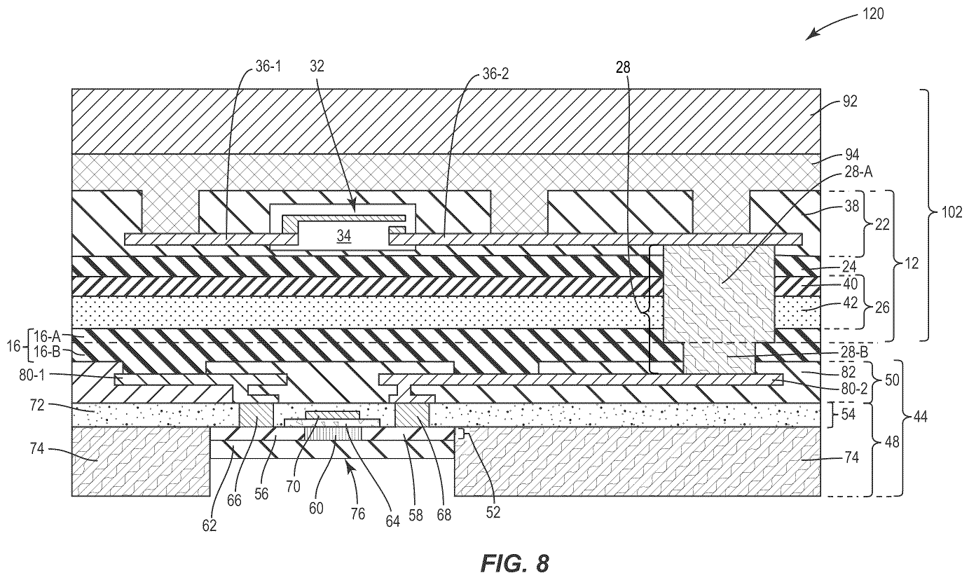

Due to the narrow gap nature of the SiGe material, it is possible that the interfacial layers 108 may be conductive (for some type of devices). The interfacial layers 108 may cause current leakage between the source 56 and the drain 58 of the FEOL portion 48. Therefore, in some applications, such as FET switch applications, it is desirable to also remove the interfacial layers 108, as illustrated in FIG. 8. If the body 62 exists underneath the active layer 52, the body 62 will be exposed at the opening 76. The interfacial layers 108 may be removed by the same etching process used to remove the controller handle substrate 110, or may be removed by another etching process, such as a chlorine-base dry etching system (Chlorine or fluorine-based) and/or a wet etching (using TMAH, NH4OH:H2O2, H2O2, etc.). Herein, if the interfacial layer 108 is thin enough, it may not cause any leakage between the source 56 and the drain 58 of the FEOL portion 48. In that case, the interfacial layers 108 may remain (not shown).

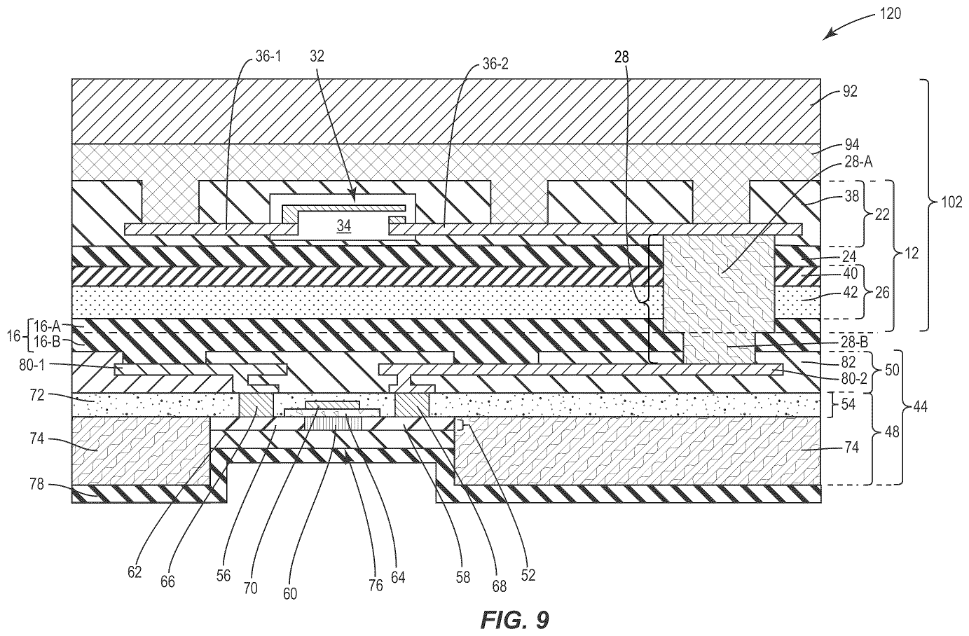

In some applications, after the removal of the controller handle substrate 110 and the interfacial layer 108, the active layer 52 may be passivated to achieve further low levels of current leakage in the device. The passivation layer 78 may be formed directly underneath the FEOL portion 48 of the controller device region 44, as illustrated in FIG. 9. Herein, the passivation layer 78 may extend over an entire bottom surface of the FEOL portion 48, such that the passivation layer 78 continuously covers exposed surfaces within the opening 76 and bottom surfaces of the isolation sections 74. In some applications, the passivation layer 78 may only cover the bottom surface of the active layer 52 (covers the bottom surface of the body 62 if the body 62 exists) and resides within the opening 76 without covering the bottom surfaces of the isolation sections 74 (not shown). The passivation layer 78 may be formed of silicon oxide by a plasma enhanced deposition process, an anodic oxidation process, an ozone-based oxidation process, and a number of other proper techniques.

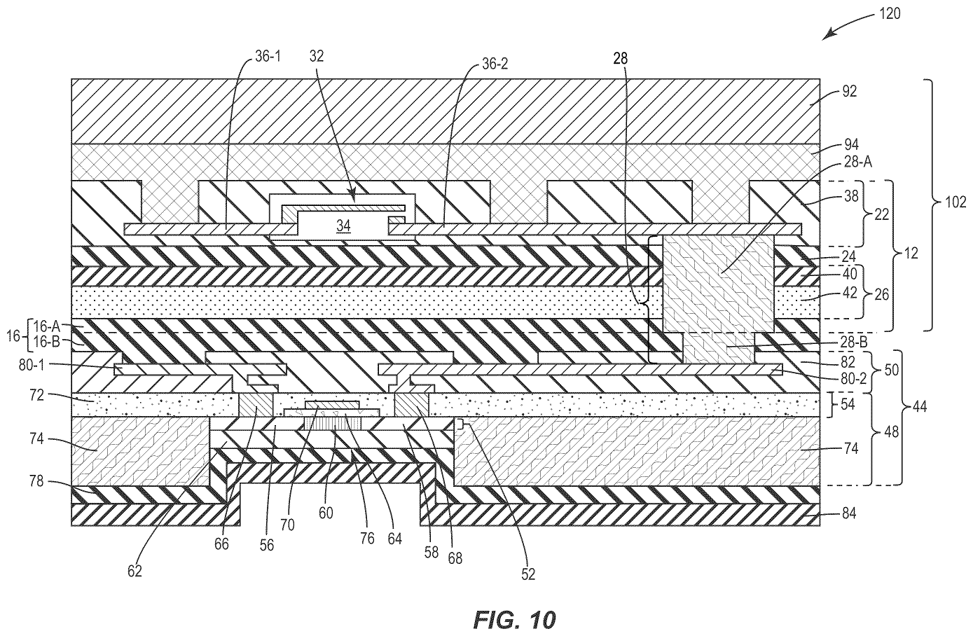

Next, the controller barrier layer 84 is applied directly underneath the passivation layer 78, as illustrated in FIG. 10. The controller barrier layer 84 is configured to provide a superior barrier to moisture and impurities, which could diffuse into the channel 60 of the active layer 52 and cause reliability concerns in the device. In addition, the controller barrier layer 84 may also be engineered so as to provide additional tensile strain to the controller device region 44. Such strain may be beneficial in providing additional improvement of electron mobility in n-channel devices. If the passivation layer 78 is formed only with the opening 76, the controller barrier layer 84 continuously covers exposed surfaces within the opening 76 (at the bottom surface of the passivation layer 78 and side surface portions of the isolation sections 74) and bottom surfaces of the isolation sections 74 (not shown). In some applications, the controller barrier layer 84, which is formed of silicon nitride with a thickness between 2000 Å and 10 μm, may further passivate the active layer 52. In such a case, there may be no need for the passivation layer 78. The controller barrier layer 84 always extends over the bottom surface of the active layer 52. The controller barrier layer 84 may be formed by a chemical vapor deposition system such as a PECVD system, or an ALD system, such as a PEALD system.

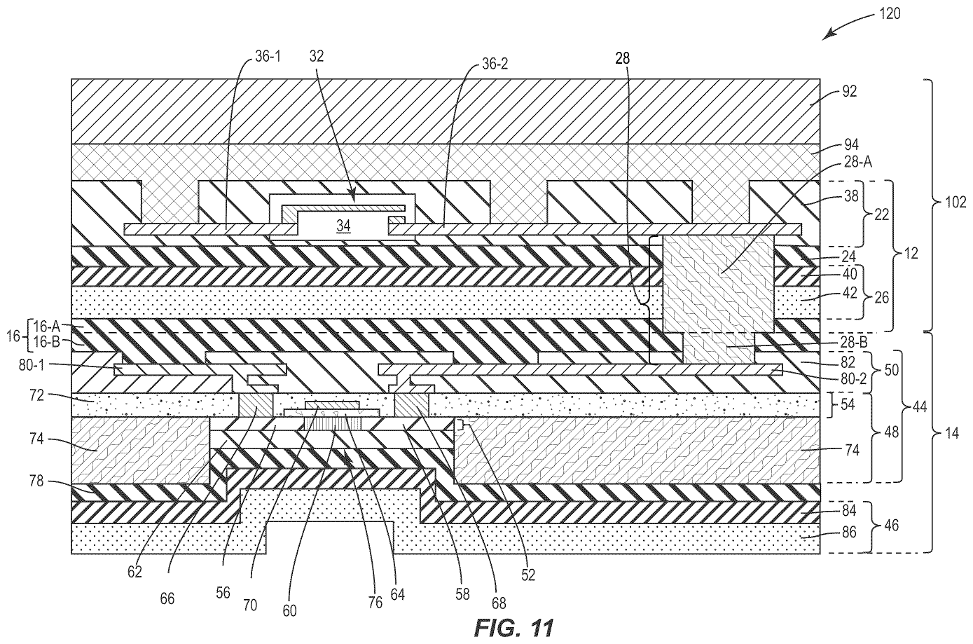

The controller thermally conductive layer 86 is then applied underneath the controller barrier layer 84 to form the controller enhancement region 46 so as to complete the controller device 14, as illustrated in FIG. 11. The controller thermally conductive layer 86, which may be formed of aluminum nitride with a thickness between 0.1 μm and 20 μm, is configured to provide superior thermal dissipation for the controller device region 44, in the order of 275 W/mk while retaining superior electrically insulating characteristics. The controller thermally conductive layer 86 might be very important to the overall thermal behavior of the stacked layers. If power dissipation is not of a concern, then the controller thermally conductive layer 86 may be omitted. The controller thermally conductive layer 86 may be formed by CVD, ALD, or other similar methods known to those skilled in the art of semiconductor processing.

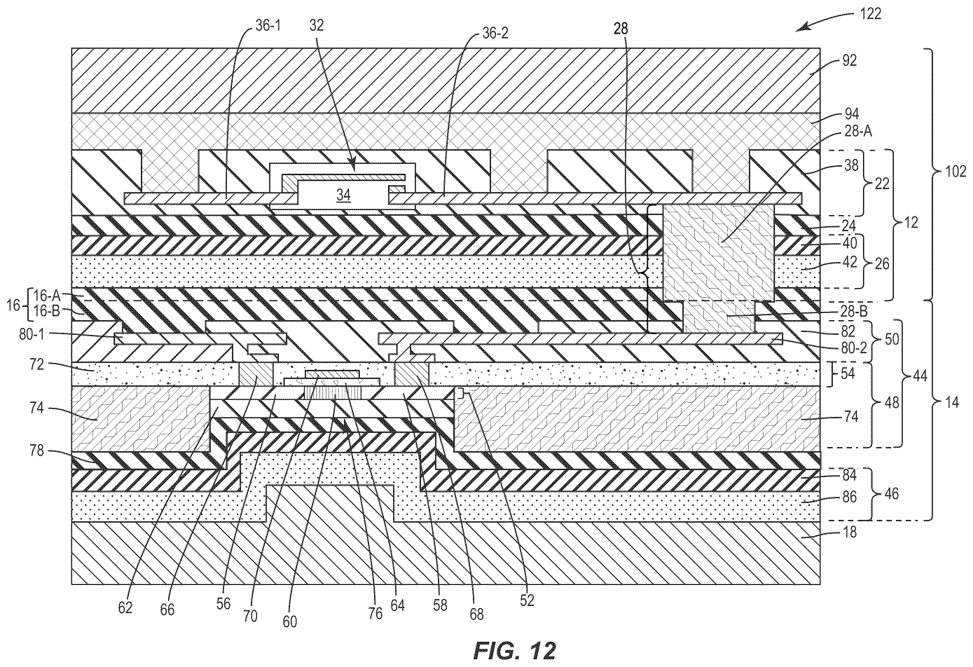

After the controller enhancement region 46 is formed, the mold compound 18 is applied underneath the controller enhancement region 46 to provide a molded package 122, as illustrated in FIG. 12. Herein, the mold compound 18 fills the opening 76 and fully covers the controller enhancement region 46. The mold compound 18 may be applied by various procedures, such as compression molding, sheet molding, overmolding, transfer molding, dam fill encapsulation, and screen print encapsulation. The mold compound 18 may have a superior thermal conductivity between 1 W/m·K and 100 W/m-K, or between 7 W/m·K and 20 W/m·K. The mold compound 18 may have a dielectric constant less than 8, or between 3 and 5. During the molding process of the mold compound 18, the temporary carrier 92 provides mechanical strength and rigidity to the package. A curing process (not shown) is then performed to harden the mold compound 18. The curing temperature is between 100° C. and 320° C. depending on which material is used as the mold compound 18. After the curing process, the mold compound 18 may be thinned and/or planarized (not shown).

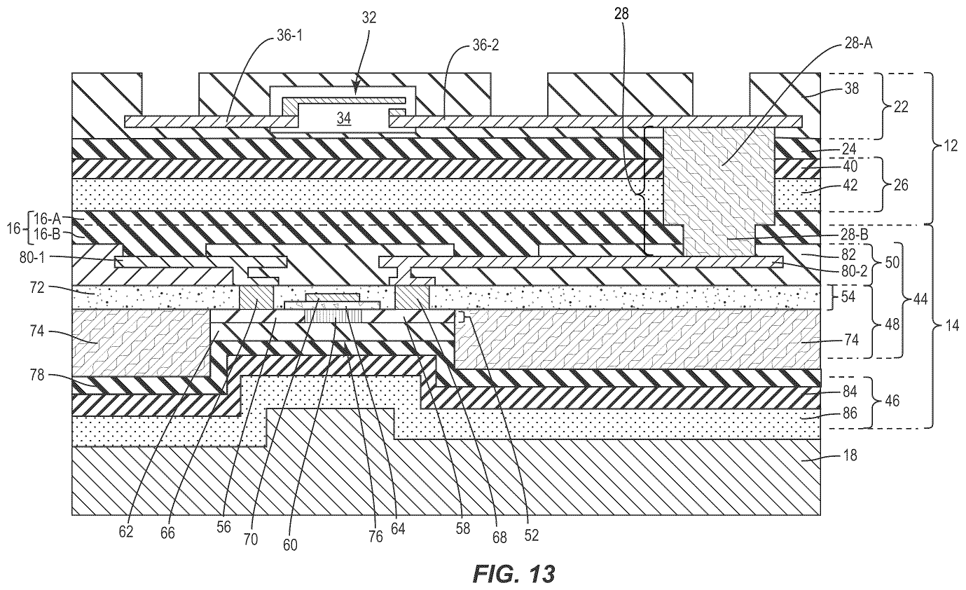

The temporary carrier 92 is then debonded from the molded package 122, and the mounting layer 94 is cleaned from the molded package 122, as illustrated in FIG. 13. A number of debonding processes and cleaning processes may be applied depending on the nature of the temporary carrier 92 and the mounting layer 94 chosen in the earlier steps. For instance, the temporary carrier 92 may be mechanically debonded using a lateral blade process with the stack heated to a proper temperature. Other suitable processes involve radiation of UV light through the temporary carrier 92 if it is formed of a transparent material, or chemical debonding using a proper solvent. The mounting layer 76 may be eliminated by wet or dry etching processes, such as proprietary solvents and plasma washing. After the debonding and cleaning process, top portions of the MEMS device region 22 are exposed. In one embodiment, one top surface portion of the first MEMS connecting layer 36-1 and two surface portions of the second MEMS connecting layer 36-2 are exposed through the MEMS dielectric layers 38, which may function as input/output (I/O) ports of the molded package 122. As such, the molded package 122 may be electrically verified to be working properly at this point.

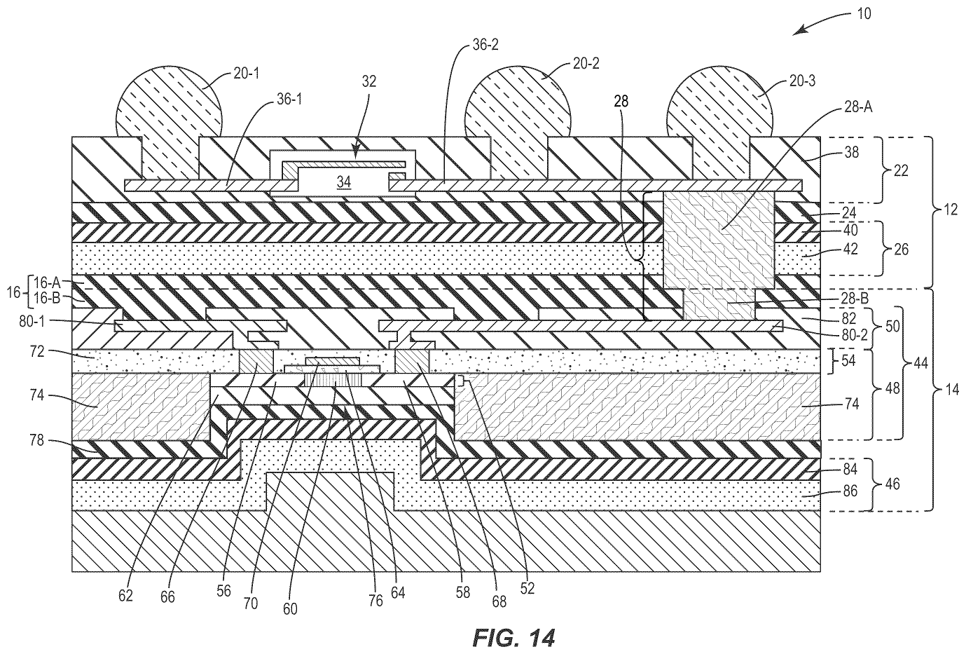

At last, a number of the bump structures 20 are formed to provide the microelectronics package 10, as illustrated in FIG. 14. Each bump structure 20 is formed at the top of the microelectronics package 10 and electrically coupled to an exposed top portion of the MEMS corresponding connecting layer 36 through the MEMS dielectric layers 38. For the purpose of this illustration, the first bump structure 20-1 is connected to the MEMS component 32 through the first MEMS connecting layer 36-1, while the second bump structure 20-2 and the third bump structure 20-3 are connected to the MEMS component 32 through the second MEMS connecting layer 36-2. In addition, the second bump structure 20-2 and the third bump structure 20-3 are connected to the FET provided in the controller device region 44 through the second MEMS connecting layer 36-2, the through-via structure 28, and the second controller connecting layer 80-2. In addition, each bump structure 20 protrudes vertically from the MEMS dielectric layers 38.

Those skilled in the art will recognize improvements and modifications to the preferred embodiments of the present disclosure. All such improvements and modifications are considered within the scope of the concepts disclosed herein and the claims that follow.

What is claimed is:

1. A method of fabricating a microelectronics package comprising:
forming a first wafer with a first device and a first through-via, wherein:
the first device comprises a first device region and a stop layer underneath the first device region, wherein the first device region includes a first component and a plurality of first connecting layers; and
the first through-via extends from the first device region and is exposed through the stop layer, and at least one of the plurality of first connecting layers is configured to electrically connect the first component to the first through-via;
forming a second wafer that comprises a second device region, a bonding layer over the second device region, and a second through-via, wherein:
the second device region includes a second component and a plurality of second connecting layers; and
the second through-via extends from the second device region and is exposed through the bonding layer, and at least one of the plurality of the second connecting layers is configured to electrically connect the second component to the second through-via; and
bonding the first wafer to the second wafer, such that the first wafer is vertically stacked with the second wafer, wherein:
the bonding layer of the second wafer is configured to bond to the first wafer; and
the first through-via exposed through the stop layer and the second through-via exposed through the bonding layer are bonded directly together to form a through-via structure, which extends from the first device region, at least extends through the stop layer and the bonding layer, and extends into the second device region, such that the second component in the second device region is electrically connected to the first component in the first device region through the plurality of second connecting layers, the through-via structure, and the plurality of first connecting layers.

2. The method of claim 1 wherein:
the first device is a microelectromechanical systems (MEMS) device, and the first component within the first device region is a MEMS component; and
the second component within the second device region is a controlling component, such that the controlling component in the second device region is configured to control the MEMS component in the MEMS device through the second connecting layer, the through-via structure, and the first connecting layer.

3. The method of claim 1 wherein:
the first through-via does not extend toward or into portions of the first device region where the first component is located; and
the second through-via does not extend toward or into portions of the second region where the second component is located.

4. The method of claim 1 wherein:
the stop layer in the first wafer is formed of silicon oxide, and the bonding layer in the second wafer is formed of silicon oxide; and
when the first wafer is bonded to the second wafer, the stop layer in the first wafer is directly bonded with the bonding layer of the second wafer, wherein silicon crystal, which has no germanium, nitrogen, or oxygen content, does not exist between the first device region and the second device region.

5. The method of claim 1 wherein the first device further comprises a first enhancement region underneath the stop layer and an extra bonding layer underneath the first enhancement region, wherein:
within the first wafer, the first through-via extends from the first device region, extends through the stop layer and the first enhancement region, and is exposed through the extra bonding layer;
the extra bonding layer in the first wafer is formed of silicon oxide, and the bonding layer in the second wafer is formed of silicon oxide; and
when the first wafer is bonded to the second wafer, the extra bonding layer in the first wafer and the bonding layer of the second wafer are bonded directly together to form a bonding region, wherein the through-via structure extends from the first device region, extends through the stop layer, the first enhancement region, and the bonding region, and extends into the second device region.

6. The method of claim 5 wherein:
the first enhancement region includes a first barrier layer underneath the stop layer and a first thermally conductive layer underneath the first barrier layer;
the first barrier layer is formed of silicon nitride with a thickness between 0.2 μm and 10 μm; and
the first thermally conductive layer is formed of aluminum nitride with a thickness between 0.1 μm and 20 μm.

7. The method of claim 5 wherein silicon crystal, which has no germanium, nitrogen, or oxygen content, does not exist between the first device region and the second device region.

8. The method of claim 1 wherein:
the first through-via and the second through-via are formed of copper; and
the first through-via and the second through-via are bonded by a hybrid copper-copper bonding process.

9. The method of claim 1 wherein the second device region includes a back-end-of-line (BEOL) portion underneath the bonding layer, and a front-end-of-line (FEOL) portion underneath the BEOL portion, wherein:
the FEOL portion comprises a contact layer underneath the BEOL portion, an active layer underneath the contact layer, and isolation sections underneath the contact layer and surrounding the active layer, wherein a combination of the active layer and the contact layer provides the second component; and
the BEOL portion comprises dielectric layers, and the plurality of second connecting layers, wherein the plurality of second connecting layers is partially covered by the dielectric layers and is configured to electrically connect the second component in the FEOL portion to components outside the second device region.

10. The method of claim 9, wherein the isolation sections extend vertically beyond a bottom surface of the active layer to define an opening within the isolation sections and underneath the active layer.

11. The method of claim 10 further comprising forming an enhancement region underneath the FEOL portion of the second device region, wherein the enhancement region continuously covers bottom surfaces of the isolation sections and exposed surfaces within the opening so as to cover the active layer.

12. The method of claim 11 wherein forming the enhancement region comprises:
forming a barrier layer continuously covering the bottom surfaces of the isolation and the exposed surfaces within the opening so as to cover the active layer; and
forming a thermally conductive layer continuously covering the barrier layer.

13. The method of claim 12, wherein:
the barrier layer is formed of silicon nitride with a thickness between 0.2 μm and 10 μm; and
the thermally conductive layer is formed of aluminum nitride with a thickness between 0.1 μm and 20 μm.

14. The method of claim 11 further comprising forming a passivation layer underneath the FEOL portion of the second device region, wherein:
the passivation layer is formed of silicon dioxide;
the passivation layer continuously covers bottom surfaces of the isolation sections and exposed surfaces within the opening so as to cover the active layer; and
the enhancement region is formed underneath the passivation layer.

15. The method of claim 11 further comprising applying a mold compound underneath the enhancement region, wherein the mold compound has a thermal conductivity greater than 1 W/m·K and a dielectric constant less than 8.

16. The method of claim 9, wherein a bottom surface of each isolation section and the bottom surface of the active layer are coplanar, such that the FEOL portion of the second device region has a flat bottom surface.

17. The method of claim 16 further comprising forming an enhancement region underneath the FEOL portion of the second device region, wherein the enhancement region continuously covers the bottom surfaces of the isolation sections and the bottom surface of the active layer.

18. The method of claim 17 wherein forming the enhancement region comprises:
forming a barrier layer continuously covering the bottom surfaces of the isolation sections and the bottom surface of the active layer; and
forming a thermally conductive layer continuously covering the barrier layer.

19. The method of claim 18, wherein:
the barrier layer is formed of silicon nitride with a thickness between 0.2 μm and 10 μm; and
the thermally conductive layer is formed of aluminum nitride with a thickness between 0.1 μm and 20 μm.

20. The method of claim 1 further comprising forming a plurality of bump structures, wherein:
the first device region further comprises first dielectric layers;
the plurality of first connecting layers is partially covered by the first dielectric layers and is configured to electrically connect the first component to components outside the first device region; and
the plurality of bump structures is formed over the first device region, and electrically coupled to the first component through the plurality of first connecting layers.

21. A microelectronics package comprising:
a first device comprising a first device region and a stop layer underneath the first device region, wherein the first device region includes a first component and a first connecting layer;
a second device, which is vertically stacked underneath the first device, comprising a bonding layer configured to bond to the first device and a second device region underneath the bonding layer, wherein the second device region includes a second component and a second connecting layer; and
a through-via structure, which extends from the first device region, at least extends through the stop layer and the bonding layer, and extends into the second device region, wherein:
the first connecting layer is configured to electrically connect the first component with the through-via structure, and the second connecting layer is configured to electrically connect the second component with the through-via structure, such that the second component in the second device region is electrically connected to the first component in the first device region through the second connecting layer, the through-via structure, and the first connecting layer.
